(19) United States
(12) Patent Application Publication
(10) Pub. No.: US 2011/0278928 A1
(43) Pub. Date: Nov. 17, 2011

(54) WIND-POWERED DATA CENTER

(75) Inventors: Douglas C. Burger, Redmond, WA (US); Eric C. Peterson, Woodinville, WA (US); Sompong Paul Olarig, Woodinville, WA (US); Mark E. Shaw, Sammamish, WA (US); David Kim, Kirkland, WA (US); Christian L. Belady, Mercer Island, WA (US)

(73) Assignee: MICROSOFT CORPORATION, Redmond, WA (US)

(21) Appl. No.: 12/781,445

(22) Filed: May 17, 2010

(51) Int. Cl. H02J 3/14; H05K 7/20; H02J 7/34; F03D 9/00

(52) U.S. Cl. 307/39; 700/286; 713/300; 290/55; 361/692; 307/66

(57) ABSTRACT

This document describes various techniques for powering a computer data center using a wind-powered generator. The computer data center may include network connected servers that are electrically connected to, and powered by, the wind-powered generator.

### BACKGROUND

Computer data centers, that include network-connected computer servers that receive, process, store, and transmit data, utilize an immense amount of power to operate. Conventionally, therefore, computer data centers are connected to the power grid. As the amount of data stored on and transmitted over the Internet increases, however, more and more computer servers are utilized which is causing the amount of available power to become a scare resource and a resultant increase in the amount of carbon emitted to power servers.

### SUMMARY

This document describes various techniques for powering computer data centers using wind-powered generators. A data center may include network connected servers that are electrically connected to, and powered by, a wind-powered generator that generates power by converting the energy of wind into electricity used to power the data center. The wind-powered generator may include blades mounted on top of a hollow tower. When the wind blows, the blades rotate to convert the energy of wind into kinetic energy. The kinetic energy is then converted to electricity used to power the data center. Server containers, configured to hold the servers, may be mounted to an outer wall at the bottom of the tower to form a supportive base for the tower. In some embodiments the hollow tower of the wind-powered generator may be used as a chimney to cool the servers.

In some embodiments excess power generated by the wind-powered generator may be redistributed to an alternate source, such as a battery storage device. The excess power may then be drawn from the battery storage device, at a later time, to provide power to the data center when the wind-powered generator generates insufficient power for the data center. In other embodiments one or more of the servers may be selectively turned off or throttled down into a lower performing state when the wind-powered generator is generating insufficient power for the data center.

This Summary is provided to introduce a selection of concepts in a simplified form that are further described below in the Detailed Description. This Summary is not intended to identify key or essential features of the claimed subject matter, nor is it intended to be used as an aid in determining the scope of the claimed subject matter.

### BRIEF DESCRIPTION OF THE DRAWINGS

The detailed description is described with reference to the accompanying figures. In the figures, the left-most digit of a reference number identifies the figure in which the reference number first appears. The use of the same reference number in different instances in the description and the figures may indicate similar or identical items.

FIG. 1 illustrates an example operating environment.

FIG. 2 illustrates an example server of FIG. 1 in more detail.

FIG. 3a illustrates an example wind-powered data center.

FIG. 3b illustrates the example wind-powered data center when using a tower of the data center as a chimney to cool servers in the data center.

FIG. 4 is a flow diagram depicting an example process for distributing power from a wind-powered generator to power a data center.

### DETAILED DESCRIPTION

Overview

This document describes various techniques for powering computer data centers using wind-powered generators. A data center may include network connected servers that are electrically connected to, and powered by, a wind-powered generator. The wind-powered generator may include blades mounted on top of a hollow tower. When the wind blows, the blades rotate on an axis to convert the energy of wind into kinetic energy. The kinetic energy is then converted to electricity used to power the data center. Server containers, configured to hold the servers, may be mounted to an outer wall at the bottom of the tower to form a supportive base for the tower. In some embodiments the hollow tower of the wind-powered generator may be used as a chimney to cool the servers.

In some embodiments excess power generated by the wind-powered generator may be redistributed to an alternate source, such as a battery storage device. The excess power may then be drawn from the battery storage device, at a later time, to provide power to the data center when the wind-powered generator generates insufficient power for the data center. In other embodiments one or more of the servers may be selectively turned off or throttled down into a lower performing state when the wind-powered generator is generating insufficient power for the data center.

Example Environment

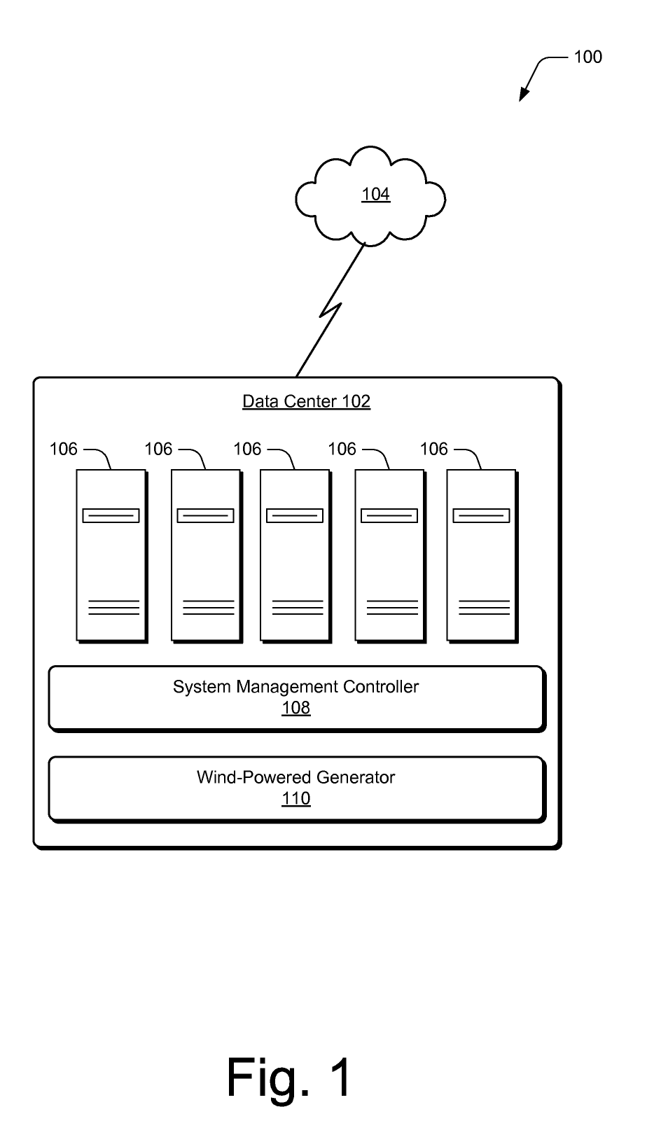

FIG. 1 is an illustration of an example environment 100 having a data center 102 and a communication network 104, through which data center 102 may communicate. Data center 102 includes one or more server(s) 106 and a system management controller 108 that may reside on any of server(s) 106 and/or separate and apart from server(s) 106, such as on a separate computing device. Data center 102 is configured to receive and transmit data via communication network 104 and to store and process the data. While data center 102 is described and illustrated as containing one or more servers, it is to be appreciated that data center 102 may include any computing devices that in combination implement a system that may receive, store, process, and transmit data. For example, server(s) 106 may be any device capable of communicating over a network (e.g., communication network 104), writing data to a storage medium, and/or reading from a storage medium or any combination thereof. Server(s) 106 may comprise, by way of example and not limitation, a desktop computer, a mobile computer, or a mobile device. Communication network 104 may include any suitable network such as the Internet, a local-area network, a wide-area network, a wireless-network, a personal-area network, a dial-up network, and/or a USB bus, to name a few.

Data center 102 is powered by a wind-powered generator 110 that generates power by converting the energy of wind into kinetic energy. The kinetic energy is then converted to electricity used to power data center 102. In some embodiments wind-powered generator 110 may generate enough electricity to completely power data center 102 thereby eliminating use of the power grid by the data center 102. Data center 102, therefore, may be simply connected to a network, such as the internet, in order to receive and transmit data across the network.

As described in more detail below, system management controller 108 is configured to control the distribution of power from wind-powered generator 110 to the one or more server(s) 106 in order to enable the servers to process, store, receive, and transmit data.

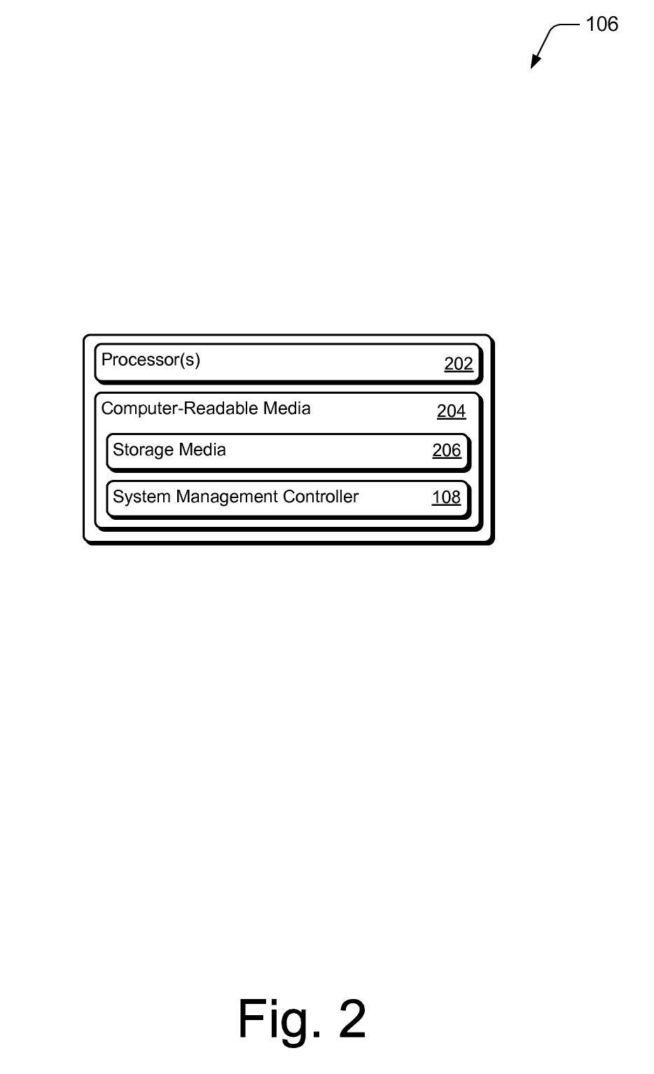

FIG. 2 illustrates an example server 106 of FIG. 1 in more detail. Server 106 includes processor(s) 202 and computer-readable media (CRM) 204. Computer-readable media 204 contains storage media 206. Computer-readable media 204 may also contain system management controller 108 of FIG. 1. System management controller 108 may be located on any of server(s) 106 and/or separate and apart from server(s) 106, such as on a separate computing device. System management controller 108 is described as part of the processes discussed below. Storage media 206 includes internal and/or external (but local) memory and is capable of storing data.

Generally, any of the techniques and abilities described herein can be implemented using software, firmware, hardware (e.g., fixed-logic circuitry), or any suitable combination of these implementations. The example server 106 generally represents software, firmware, hardware or any combination thereof. In the case of a software implementation, for instance, system management controller 108 represents computer-executable instructions (e.g., program code) that perform specific tasks when executed on a processor (e.g., CPU or CPUs). The program code can be stored in one or more computer-readable memory devices, such as computer readable media 204 and/or storage media 206. The features and techniques described herein are platform-independent, meaning that they may be implemented on a variety of commercial computing platforms having a variety of processors.

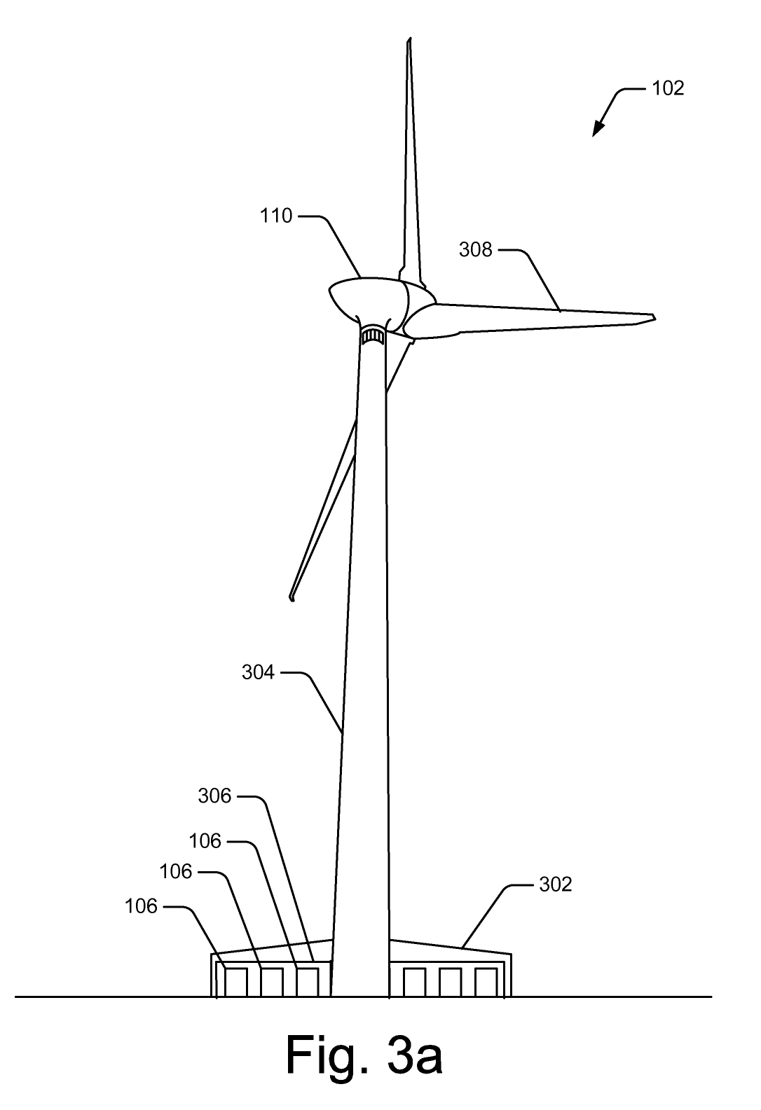

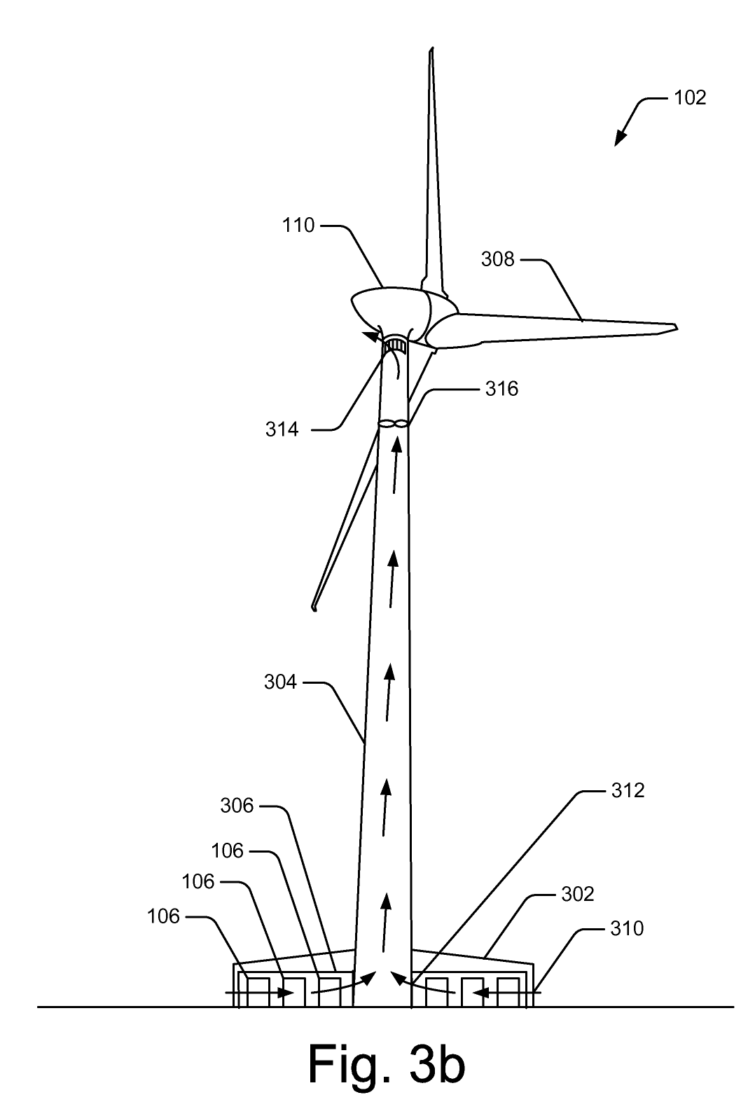

FIG. 3a illustrates an example data center 102 of FIG. 1 in more detail. Data center 102 includes one or more server(s) 106 located in a base 302 that supports a hollow tower 304 of wind-powered generator 110. In some embodiments, the servers are located within one or more server container(s) 306 that fit inside base 302. It is to be appreciated, therefore, that the location of the servers takes advantage of the space occupied by base 302. In some embodiments six pre-fabricated server containers may be used to form a hexagon base to support the tower. It is to be appreciated, however, that any number and/or configuration of server container(s) 306 may be used. Alternately or additionally, because tower 304 is hollow, one or more server(s) 106 may be secured to an inner wall of the tower.

Wind-powered generator 110 includes blades 308 that rotate on an axis, when the wind blows, to convert the energy of wind into kinetic energy. The kinetic energy is then converted into electricity used to power data center 102. In FIG. 3a, wind-powered generator 110 includes three blades that rotate on a horizontal axis. It is to be appreciated, however, that any type of wind-powered generator may be used. For instance, in some embodiments the wind-powered generator may include blades that rotate on a vertical axis. In other embodiments, the wind-powered generator may comprise an “eggbeater” turbine.

Wind-powered generator 110 may be electrically coupled directly to server(s) 106. Co-locating the wind-powered generator with the servers of data center 102 reduces the amount of power that is conventionally lost due to power conversion thereby increasing the power efficiency of data center 102.

Tower 304 may also be used as a chimney to cool the servers of data center 102 through natural convection. Note that servers operate best within an operational temperature range. When servers are run, however, they generate heat which may increase the temperature of the servers to a temperature that is above the operational temperature range. Conventionally, fans are used to keep servers cool and to ensure that the servers do not heat to a temperature above the operational temperature range. Fans, however, use power to operate.

The use of server fans may be reduced or eliminated by using the tower as a chimney to provide air flow to the servers. Natural ventilation can be created by providing vents at the top of the tower to allow warm air from the servers to rise by convection and escape to the outside. At the same time cooler outside air can be drawn in through vents in the server containers. In addition, the tower creates a natural updraft that is directly proportional to the height of the tower. The updraft helps to pull the warm air up and out of the tower. By using the tower as a chimney, the number of server fans and the amount of power conventionally used to power the server fans may be reduced, thereby improving the power usage effectiveness of data center 102.

FIG. 3b illustrates an example data center 102 of FIG. 1 when using tower 304 as a chimney to cool servers 106. Arrows are used to illustrate the flow of air into containers 306 and up and out of tower 304. As illustrated in FIG. 3b, server containers 306 include outer vents 310 that allow outside cool air to flow into the containers. The cool air cools servers 106 in server containers 306 and becomes warm air. The warm air inside containers 306 then flows out of containers 306 and into tower 304 through inner vents 312. Once inside tower 304, the warm air naturally rises up the tower 304 by convection, and by the updraft created by the tower, and exits out of exhaust vents 314 at the top of the tower 304.

System management controller 108 may control the temperature inside containers 306 to keep the temperature within the operational temperature range of the servers. The system management controller can cause outer vents 310, inner vents 312, and exhaust vents 314 to open or close in order to keep servers 106 within the operational temperature range. For example, system management controller 110 may cause vents 310, 312, and 314 to open responsive to determining that the servers need to be cooled. When vents 310, 312, and 314 are open, cool air flows into containers 306 and up and out of tower 304 as described above. Alternately, system management controller 110 can cause one or more of vents 310, 312, or 314 to be closed to allow the servers to heat the container responsive to determining that the servers are to be heated. In this way the system management controller may control the temperature of the servers to ensure that the temperature stays within the operational temperature range by opening and closing vents 310, 312, and 314 thereby using outside air for cooling and the heat of the servers for heating.

FIG. 3b illustrates just one example of using the tower of a wind-powered generator as a cooling chimney. It is to be appreciated, however, that other implementations are contemplated. For example, in some embodiments outside air may be led through underground tunnels to cool the air before allowing the air to enter the containers. Alternately or additionally, trees may be planted next to the server containers to provide shade to create cooler outside air. In at least one embodiment a blower 316, such as a fan or a small wind turbine, may be mounted inside tower 304 to generate additional power from the hot air flow through the tower. The air flow up the tower causes blades of the blower to rotate thereby generating kinetic energy that may be used to provide supplemental power to the data center. In addition, the blower may be used to help draw heat up the tower and away from the servers. Furthermore, during cold weather the system management controller may cause the blower to blow air back down the tower to prevent heat from exhausting through the exhaust vents thereby keeping the temperature within the operational temperature range.

Data center 102 may be designed so that the power generated by wind-powered generator 110 is adequate to power data center 102. It is to be appreciated, however, that wind is an unpredictable power source and may blow at varying velocities causing varying amounts of power to be generated. An excess amount of power may be generated by the wind-powered generator when the wind blows at a higher velocity, e.g., higher than normal. As described herein, excess power refers to a situation in which the wind-powered generator is generating more power than is used to power the data center 102. Conversely, an insufficient amount of power may be generated by the wind-powered generator when the wind blows at a velocity that is less than within an operational range. As described herein, insufficient power refers to a situation in which the wind-powered generator is generating less power than the power that is to be used by the data center.

In order to account for the unpredictability of the wind-powered generator, one or more additional power sources may be used to supplement the power generated by the wind-powered generator. In some embodiments, for instance, data center 102 may be connected to the power grid and power may be drawn from the power grid when insufficient power is generated by the wind-powered generator. Note that in these situations the power grid would be used to provide emergency power to the data center, but that the wind-powered generator would still be the primary source of power for the data center. Alternately of additionally, solar panels may be used to generate solar power that may be used to supplement the power generated by the wind-powered generator. For example, solar panels may be mounted along the sides of tower 304. Similarly, if the data center is close to a flowing water source, water turbines may be used to generate additional power. It is to be appreciated, therefore, that a variety of different power sources may be used to supplement the power generated by the wind-powered generator.

Example Processes

The following discussion describes techniques of distributing power from the wind-powered generator to power the data center. Aspects of these processes may be implemented in hardware, firmware, software, or a combination thereof. These processes are shown as sets of blocks that specify operations performed, such as through one or more entities or devices, and are not necessarily limited to the order shown for performing the operations by the respective blocks. In portions of the following discussion reference may be made to environment 100 of FIG. 1 and to data center 102 of FIG. 3a.

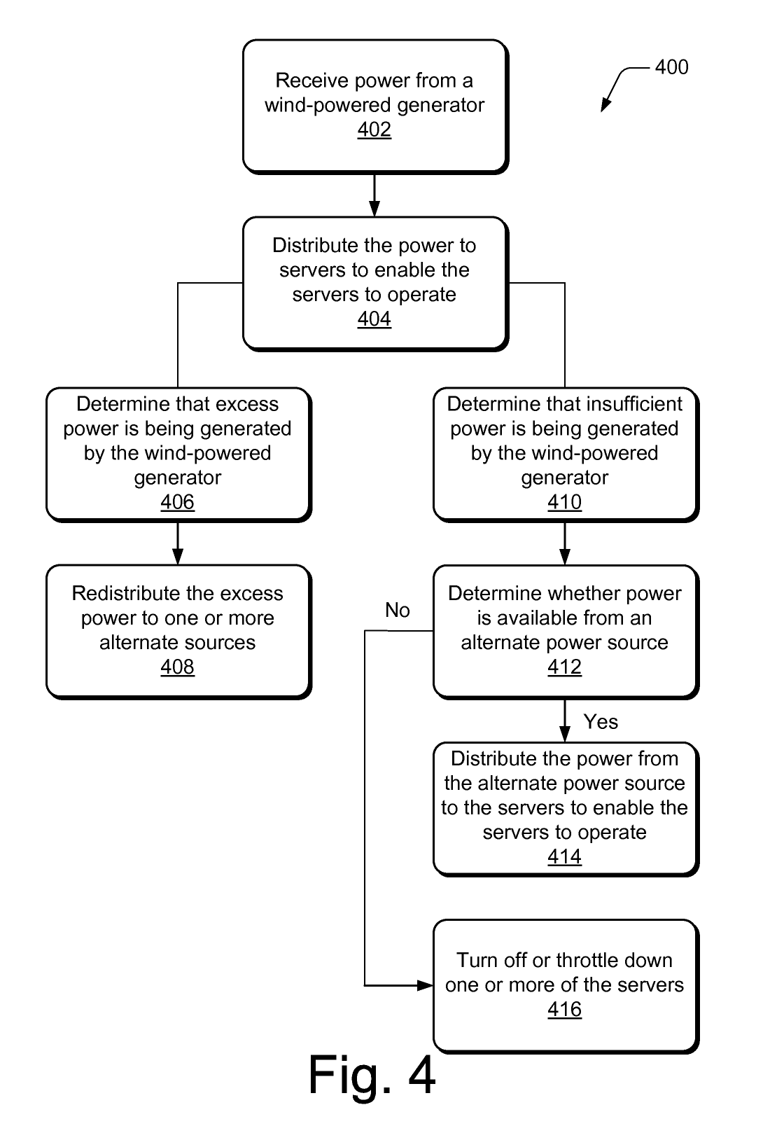

FIG. 4 is a flow diagram depicting an example process 400 for distributing power from the wind-powered generator to power the data center. Block 402 receives power from a wind-powered generator. By way of example, consider process 400 in the context of environment 100 and data center 102 of FIG. 3a. Data center 102 receives power from wind-powered generator 110 being generated by the rotation of blades 308.

Block 404 distributes the power to servers to enable the servers to operate. Continuing with the ongoing example, system management controller 108 distributes the power generated by wind-powered generator 110 to servers 106 of data center 102 to enable the servers to operate.

Block 406 determines that excess power is being generated by the wind-powered generator. As described above, excess power refers to the situation in which the wind-powered generator is generating more power than is needed to power the data center which may occur when the velocity of wind is higher than normal. Continuing with the ongoing example, system management controller 108 determines that excess power is being generated by wind-powered generator 110.

Block 408 redistributes the excess power to one or more alternate sources. In some embodiments excess power may be redistributed to a battery storage device. For example, the excess power may be redistributed to an uninterruptible power source that is configured to provide emergency power to the data center. The uninterruptible power source may include one or more attached batteries and is configured to store the excess power to be used at a later time, such as a period when the power generated by the wind-powered generator is insufficient to power the data center. In some embodiments the data center may be connected to the power grid. Utility companies may be willing to buy excess power from the data center. When excess power is generated by the wind-powered generator, therefore, the excess power may be redistributed and/or sold back to the power grid. Continuing with the ongoing example, system management controller 108 redistributes the excess power generated by wind-powered generator 110 to one or more alternate sources, such as battery storage device or the power grid, to name just a few.

Alternately, block 410 determines that insufficient power is being generated by the wind-powered generator. As described above, the wind-powered generator may generate insufficient power to power the data center when the velocity of the wind is lower than normal. Block 412 determines whether power is available from an alternate source that can be used to make up for the insufficient power from the wind-powered generator. For example, system management controller 110 may determine whether power is available from a battery storage device or from the power grid. Block 414 distributes the power from the alternate power source to the servers to enable the servers to operate responsive to determining that power is available from the alternate power source. Continuing with the ongoing example, system management controller 108 distributes power from an alternate power source, such as a battery storage device or the power grid, to one or more servers 106 to enable the servers to operate.

Alternately, block 416 turns off or throttles down one or more of the servers responsive to determining that power is not available from an alternate power source. For example, one or more servers may be turned off or throttled down to a lower performing state to decrease the amount of power used by the data center. In this way, the data center may continue to operate even though all of the servers may not be operating at full capacity. The system management controller is configured to determine which servers may be turned off or throttled down with the smallest impact on the operation of the data center. Continuing with the ongoing example, system management controller 108 turns off or throttles down one or more servers 106 to enable data center 102 to operate.

### CONCLUSION

This document describes various techniques for powering computer data centers using wind-powered generators. A data center may include network connected servers that are electrically connected to, and powered by, a wind-powered generator that generates power by converting the energy of wind into electricity used to power the data center. The wind-powered generator may include blades mounted on top of a hollow tower. When the wind blows, the blades rotate to convert the energy of wind into kinetic energy. The kinetic energy is then converted to electricity used to power the data center. Server containers, configured to hold the servers, may be mounted to an outer wall at the bottom of the tower to form a supportive base for the tower. In some embodiments the hollow tower of the wind-powered generator may be used as a chimney to cool the servers.

In some embodiments excess power generated by the wind-powered generator may be redistributed to an alternate source, such as a battery storage device. The excess power may then be drawn from the battery storage device, at a later time, to provide power to the data center when the wind-powered generator generates insufficient power for the data center. In other embodiments one or more of the servers may be selectively turned off or throttled down into a lower performing state when the wind-powered generator is generating insufficient power for the data center.

What is claimed is:

1. A system comprising:
one or more servers connected to a network and configured to receive, process, store, and transmit data over the network;
a wind-powered generator configured to provide power to the system, the power originating from wind and not a power grid;
a system management controller configured to distribute the power to the one or more servers to enable the one or more servers to operate.

2. The system as recited in claim 1, wherein the wind-powered generator includes blades mounted to the top of a tower that is at least partially hollow, the blades configured to rotate when the wind blows to generate the power.

3. The system as recited in claim 2, wherein at least one of the one or more servers are mounted within the hollow portion of the tower.

4. The system as recited in claim 2, further comprising one or more server containers configured to contain the one or more servers, the one or more server containers mounted to an outer wall of the tower to form a supportive base for the tower.

5. The system as recited in claim 4, wherein the one or more server containers include an outer vent, wherein the outer wall of the tower includes an inner vent, wherein a top portion of the tower includes an exhaust vent, and wherein the outer vent, the inner vent, the hollow portion of the tower, and the exhaust vent comprises a cooling system configured to:
draw cool air in the outer vent and across the one or more servers where the cool air is warmed by the one or more servers to create warm air;
draw the warm air through the inner vent and up the hollow portion of the tower; and
release the warm air out the exhaust vent.

6. The system as recited in claim 5, wherein the system management controller is further configured to control the temperature of the one or more servers by opening and closing the outer vent, the inner vent, and the exhaust vent.

7. The system as recited in claim 1, wherein the system management controller is further configured to redistribute excess power from the wind-powered generator to an alternate source responsive to determining that the power from the wind-powered generator is greater than an amount needed to power the system.

8. The system as recited in claim 7, wherein the alternate source comprises at least one of a battery storage device or the power grid.

9. The system as recited in claim 1, wherein the system management controller is further configured to selectively turn off or throttle down at least one of the one or more servers responsive to determining that the power provided by the wind-powered generator is insufficient to power the system.

10. The system as recited in claim 1, wherein the system management controller is further configured to distribute power from an alternate power source to the one or more servers to enable the servers to operate responsive to determining that the power provided by the wind-powered generator is insufficient to power the one or more servers.

11. The system as recited in claim 10, wherein the alternate power source comprises at least one of a battery storage device or the power grid.

12. The system as recited in claim 1, wherein the system is not connected to the power grid.

13. A method comprising:
receiving power from a wind-powered generator that is electrically connected to a data center; and
distributing the power to one or more servers of the data center to enable the servers to operate.

14. The method as recited in claim 13, further comprising redistributing excess power from the wind-powered generator to an alternate source responsive to determining that the power from the wind-powered generator is greater than an amount needed to enable the servers to operate.

15. The method as recited in claim 14, wherein the alternate source comprises at least one of a battery storage device or a power grid.

16. The method as recited in claim 13, further comprising distributing power from an alternate power source to the one or more servers to enable the one or more servers to operate responsive to determining that the power provided by the wind-powered generator is insufficient to power the one or more servers.

17. The method as recited in claim 13, further comprising selectively turning off or throttling down at least one of the one or more servers responsive to determining that the power provided by the wind-powered generator is insufficient to power the one or more servers.

18. A computer data center comprising:
a wind-powered generator configured to provide power to the computer data center using blades mounted on top of a hollow tower, the blades configured to rotate when the wind blows to generate the power;
server containers configured to hold network connected servers that are electrically connected to the wind-powered generator, the server containers mounted to an outer wall of the tower to form a supportive base for the tower;
a system management controller configured to:
control the temperature of the server containers by opening and closing vents in the server containers to allow outside air to flow into the server containers;
redistribute excess power from the wind-powered generator to one or more alternate power sources; and
turn off or throttle down one or more of the servers responsive to determining that the wind-powered generator is generating an insufficient amount of power to power each of the servers.

19. The computer data center as recited in claim 18, wherein the computer data center is not connected to a power grid.

20. The computer data center as recited in claim 18, wherein the system management controller is further configured to control the temperature of the server containers by opening an inner vent and an exhaust vent in the hollow tower to allow warm air to flow from the server containers into the tower through the inner vent, and to flow up the tower and out of the tower through the exhaust vent.
